(19) United States
(12) Patent Application Publication
(10) Pub. No.: US 2024/0332136 A1
(43) Pub. Date: Oct. 3, 2024

(54) POWER SEMICONDUCTOR DEVICE WITH A STRESS-FREE JOINT BETWEEN METAL PARTS AND METHOD FOR FABRICATING THE SAME

(71) Applicant: Infineon Technologies AG, Neubiberg (DE)

(72) Inventors: Marco Bäßler, Oeversee (DE); Michal Chajneta, Lippstadt (DE); Thorsten Scharf, Lappersdorf (DE); Egbert Lamminger, Soest (DE)

(21) Appl. No.: 18/609,133

(22) Filed: Mar. 19, 2024

(30) Foreign Application Priority Data
Mar. 27, 2023 (DE) 102023202754.2

(51) Int. Cl. H01L 23/495

(52) U.S. Cl. CPC H01L 23/49537; H01L 23/49548; H01L 23/49575

(57) ABSTRACT

A power semiconductor device includes: at least one substrate; at least one power semiconductor die arranged over the at least one substrate; a first leadframe arranged over the at least one power semiconductor substrate and over the at least one power semiconductor die, the first leadframe being arranged at least partially in a first plane and including one or more connecting portions extending out of the first plane in a first direction; and a second leadframe at least partially arranged in a second plane above or below the first plane and including one or more attachment sites. The one or more connecting portions extend into the second plane at the one or more attachment sites. The one or more connecting portions are arranged at a non-zero distance from the second leadframe, the non-zero distance being bridged by weld seams at the one or more attachment sites.

### TECHNICAL FIELD

This disclosure relates in general to a power semiconductor device, in particular a power semiconductor device comprising metal parts like leadframes, wherein a stress-free or almost stress-free joint, e.g. a welded joint, between the metal parts is provided. This disclosure also relates to a method for fabricating such a power semiconductor device.

### BACKGROUND

A power semiconductor device may comprise individual metal parts that need to be connected electrically and physically. Such metal parts may e.g. be leadframe parts and may for example provide internal electrical connectors and/or external contacts of the power semiconductor device. A physical and electrical connection between such metal parts may e.g. be provided using weld seams. During fabrication of the power semiconductor device, these metal parts may be arranged next to each other in order to weld the metal parts together. However, it may be beneficial to arrange the metal parts next to each other without introducing bending stress (wherein bending stress may e.g. be introduced by touching metal parts). Bending stress may for example cause mechanical and/or electrical failures in the power semiconductor device. Improved power semiconductor devices as well as improved methods for fabricating power semiconductor devices may help in solving these and other problems.

### SUMMARY

Various aspects pertain to a power semiconductor device, comprising: at least one substrate, at least one power semiconductor die arranged over the at least one substrate, a first leadframe arranged over the at least one power semiconductor substrate and over the at least one power semiconductor die, the first leadframe being arranged at least partially in a first plane, and the first leadframe comprising one or more connecting portions extending out of the first plane in a first direction, and a second leadframe at least partially arranged in a second plane above or below the first plane, the second leadframe comprising one or more attachment sites, wherein the one or more connecting portions extend into the second plane at the one or more attachment sites, and wherein the connecting portions are arranged at a non-zero distance from the second leadframe, the non-zero distance being bridged by weld seams at the one or more attachment sites.

Various aspects pertain to a power semiconductor device, comprising: at least one substrate, at least one power semiconductor die arranged over the at least one substrate, a first leadframe arranged over the at least one substrate and over the at least one power semiconductor die, the first leadframe being arranged at least partially in a first plane, and the first leadframe comprising one or more connecting portions extending out of the first plane in a first direction, and a second leadframe at least partially arranged in a second plane above or below the first plane, the second leadframe comprising one or more attachment sites, wherein the connecting portions extend from the first plane through the attachment sites to a distal end above or below the second plane.

Various aspects pertain to a power semiconductor device, comprising: at least one substrate, at least one power semiconductor die arranged over the at least one substrate, a first leadframe arranged over the at least one substrate and over the at least one power semiconductor die, the first leadframe being arranged at least partially in a first plane, and the first leadframe comprising one or more connecting portions extending out of the first plane in a first direction, and a second leadframe at least partially arranged in a second plane above or below the first plane, the second leadframe comprising one or more attachment sites, wherein the one or more connecting portions extend into the second plane at the one or more attachment sites, and wherein at least a part of the one or more connecting portions at the attachment sites has an angle of more than 90° relative to the second plane.

Various aspects pertain to a method for fabricating a power semiconductor device, the method comprising: providing at least one substrate, arranging at least one power semiconductor die over the at least one substrate, arranging a first leadframe over the at least one substrate and over the at least one power semiconductor die such that the first leadframe is arranged at least partially in a first plane, the first leadframe comprising one or more connecting portions extending out of the first plane in a first direction, and arranging a second leadframe at least partially in a second plane above or below the first plane, the second leadframe comprising at least two attachment sites, wherein the one or more connecting portions extend into the second plane at the attachment sites, and wherein at least a part of the one or more connecting portions at the attachment sites has an angle in the range of 90° to 125° relative to the second plane.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIG. 1 shows a sectional view of a power semiconductor device comprising a first and a second leadframe, wherein the second leadframe is joined to the first leadframe via weld seams.

FIGS. 2A to 2C show a detail view of a connecting portion of the first leadframe arranged at an attachment site of the second leadframe in various stages of fabrication of the power semiconductor device.

FIGS. 3A and 3B also show a detail view of a connecting portion arranged at an attachment site according to two different examples of a power semiconductor device.

FIG. 4 shows a further exemplary power semiconductor device, wherein the connecting portions are arranged differently compared to the example shown in FIG. 1.

FIG. 5 shows a further exemplary power semiconductor device in a stage of fabrication prior to joining the first and second leadframes together by weld seams.

FIG. 6 is a flow chart of an exemplary method for fabricating a power semiconductor device.

FIG. 7 shows a plan view of the first leadframe according to a specific example.

### DETAILED DESCRIPTION

In the following detailed description, reference is made to the accompanying drawings. It may be evident, however, to one skilled in the art that one or more aspects of the disclosure may be practiced with a lesser degree of the specific details. In other instances, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless of whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The examples of a power semiconductor device described below may use various types of semiconductor chips or circuits incorporated in the semiconductor chips, among them AC/DC or DC/DC converter circuits, power MOS transistors, power Schottky diodes, JFETs (Junction Gate Field Effect Transistors), power bipolar transistors, logic integrated circuits, analogue integrated circuits, power integrated circuits, chips with integrated passives, etc. The examples may also use semiconductor chips comprising MOS transistor structures or vertical transistor structures like, for example, IGBT (Insulated Gate Bipolar Transistor) structures or, in general, transistor structures in which at least one electrical contact pad is arranged on a first main side of the semiconductor chip and at least one other electrical contact pad is arranged on a second main side of the semiconductor chip opposite to the first main side of the semiconductor chip. The semiconductor chips may comprise or consist of any suitable semiconductor material, for example Si, SiC or GaN.

An efficient power semiconductor device as well as an efficient method for fabricating a power semiconductor device may for example reduce material consumption, ohmic losses, chemical waste, etc. and may thus enable energy and/or resource savings. Improved power semiconductor devices and improved methods for fabricating a power semiconductor device, as specified in this description, may thus at least indirectly contribute to green technology solutions, i.e. climate-friendly solutions providing a mitigation of energy and/or resource use.

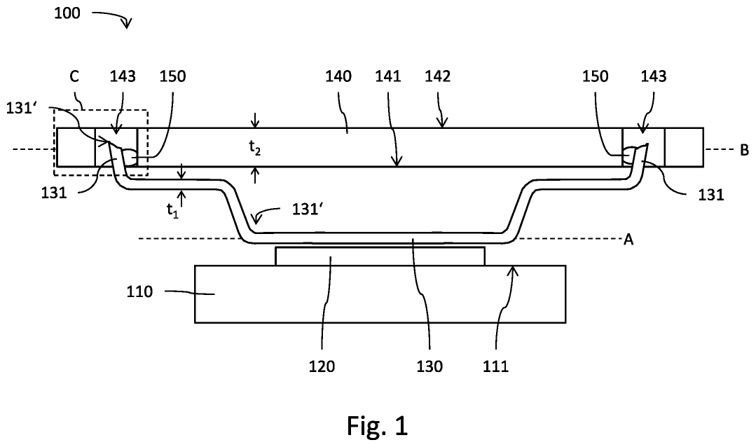

FIG. 1 shows a power semiconductor device 100 comprising at least one substrate 110, at least one power semiconductor die 120, a first leadframe 130 and a second leadframe 140.

The power semiconductor device 100 may for example comprise or consist of a power semiconductor module, in particular a power semiconductor module in a stage of fabrication. The power semiconductor device 100 may be configured to operate with a high voltage and/or a high electrical current. The power semiconductor device 100 may for example be configured for use in automotive applications. The power semiconductor device 100 may comprise any suitable electrical circuit, for example a converter circuit, an inverter circuit, a half bridge circuit, a full bridge circuit, etc.

The substrate 110 may for example be a substrate of the type direct copper bonded (DCB), direct aluminum bonded (DAB), active metal brazed (AMB), insulated metal substrate (IMS), printed circuit board (PCB), or generally any type of substrate with at least one electrically conductive layer arranged over an electrically insulating layer. According to another example, it is also possible that the substrate 110 is a metal part, e.g. a leadframe part, that does not necessarily comprise an insulating layer.

According to an example, the power semiconductor device 100 comprises a single substrate 110. According to another example, the power semiconductor device 100 comprises two, three, four or more substrates 110. The more than one substrates 110 may all be of the same type of substrate or of different types of substrates. The more than one substrates 110 may be arranged side by side such that first sides 111 of the substrates 110 are coplanar or essentially coplanar.

The power semiconductor die 120 is arranged over the substrate 110, for example over the first side 111. The power semiconductor die 120 may be electrically coupled to the substrate 110. For example, the power semiconductor die 120 may comprise a first power terminal arranged on a lower side, wherein the lower side faces the substrate 110, and wherein the first power terminal is coupled to the substrate by e.g. a soldered joint, a sintered joint, or a joint comprising conductive glue. The power semiconductor die 120 may comprise a second power terminal arranged on an upper side, wherein the upper side faces away from the substrate 110, and wherein the second power terminal is coupled to the first leadframe 130 (by e.g. a soldered joint, a sintered joint, or a joint comprising conductive glue).

In the case that the power semiconductor device 100 comprises more than one power semiconductor die 120, the power semiconductor dies 120 may be identical dies or different types of dies. Furthermore, the power semiconductor dies 120 may all be arranged over the same substrate 110 or one or more of the power semiconductor dies 120 may be arranged over one or more additional substrates 110. The first leadframe 130 and/or the second leadframe 140 may be configured to electrically connect one or more second power terminals of the power semiconductor die(s) 120 to the substrate(s) 110.

The first leadframe 130 is arranged over the one or more substrates 110 and over the one or more power semiconductor dies 120. Furthermore, the first leadframe 130 is arranged at least partially in a first plane (plane A in FIG. 1). “At least partially arranged in the first plane” may mean that a part of the first leadframe 130 is arranged in the first plane and another part of the first leadframe 130 is not arranged in the first plane. For example, 30% or more, or 50% or more, or 70% or more, or 90% or more, or almost 100% of the first leadframe 130 may be arranged in the first plane.

The first leadframe 130 may for example be configured to provide electrical connectors, e.g. contact clips, connecting the power semiconductor dies 120 to each other and/or to the substrate 110. It is also possible that the first leadframe 130 is configured to provide electrical connectors connecting the substrates 110 to each other and/or the first leadframe 130 may be configured to provide external contacts of the power semiconductor device 100. The first leadframe 130 may also comprise portions which are removed during fabrication of the power semiconductor device 100, e.g. a frame portion holding other portions in place during fabrication.

The first leadframe 130 comprises one or more connecting portions 131 which extend out of the first plane in a first direction. In the example shown in FIG. 1, the first leadframe 130 is arranged between substrate 110 and the second leadframe 140 and the connecting portions 131 extend in a direction away from the substrate 110 towards the second leadframe 140. However, it is also possible that the first leadframe 130 is arranged above the second leadframe 140 (i.e. the second leadframe 140 is arranged between the substrate 110 and the first leadframe 130). In the latter case, the connecting portions 131 may instead extend in a direction towards the substrate 110.

The one or more connecting portions 131 and the rest of the first leadframe 130 may be a monobloc part. The first leadframe 130 may have any suitable shape and any suitable dimensions. The first leadframe 130 may essentially have a uniform thickness. A thickness t₁ of the first leadframe 130 may for example be in the range of about 50 μm to about 2 mm. The lower limit of this range may also be about 100 μm, 150 μm, or 300 μm and the upper limit may also be about 1.5 mm, 1 mm, or 500 μm. According to an example, the second leadframe 140 is thicker than the first leadframe 130.

According to an example, the one or more connecting portions 131 extend further from the first plane in the first direction than any other portion of the first leadframe 130. The connecting portions 131 may be configured to be physically connected to the second leadframe 140 as described below. The connecting portions 131 may have been bent out of the first plane using e.g. a stamping process or a punching process.

The one or more connecting portions 131 may be arranged at any suitable position within the first leadframe 130. For example, connecting portions 131 may be arranged along one or more edges of the substrate 110 and/or above the first side 111 of the substrate and/or laterally next to the substrate 110.

The one or more connecting portions 131 may have any suitable shape and any suitable dimensions. For example, the connecting portions 131 may have an essentially rectangular shape as viewed from above or below the first plane. A length of the connecting portions 131, the length being measured between a distal end 131′ of a connecting portion 131 and the rest of the first leadframe 130, may for example be in the range of about 2 mm to about 10 cm. The lower limit of this range may also be about 5 mm, 1 cm, 1.5 cm, or 2 cm and the upper limit of this range may also be about 8 cm, 5 cm, or 3 cm.

The second leadframe 140 is at least partially arranged in a second plane (plane B) different from the first plane. The second plane may be arranged above the first plane (in the case that the first leadframe 130 is arranged between the substrate 110 and the second leadframe 140) or the second plane may be arranged below the first plane (in the case that the second leadframe 140 is arranged between the substrate 110 and the first leadframe 130).

The second leadframe 140 may comprise a first side 141, an opposite second side 142 and lateral sides connecting the first and second sides 141, 142. According to an example, the first leadframe 130 is completely arranged below the first side 141, except for the one or more connecting portions 131. In other words, in this case the first leadframe 130 is not arranged above the second side 142 of the second leadframe 140 (except for a part of the connecting portions 131 which may or may not extend to a point above the second side 142).

The second leadframe 140 may for example be configured to provide electrical connectors, e.g. contact clips, connecting the power semiconductor dies 120 to each other and/or to the substrate 110. It is also possible that the second leadframe 140 is configured to provide electrical connectors connecting the substrates 110 to each other and/or the second leadframe 140 may be configured to provide external contacts of the power semiconductor device 100. The second leadframe 140 may also comprise portions which are removed during fabrication of the power semiconductor device 100, e.g. a frame portion holding other portions in place during fabrication.

The second leadframe 140 comprises one or more attachment sites 143. The attachment sites 143 are configured to be connected to the connecting portions 131 of the first leadframe 130 via weld seams 150. According to an example, the attachment sites 143 comprise openings extending through the second leadframe 140 (as e.g. shown in FIG. 1). According to another example, the attachment sites are positions on one or more of the lateral sides of the second leadframe 140 that are configured to be connected to the connecting portions 131.

The second leadframe 140 may have any suitable shape and any suitable dimensions. The second leadframe 140 may essentially have a uniform thickness. According to an example, the thickness t₂ of the second leadframe 140 is greater than the thickness t₁ of the first leadframe 130, for example 1.5 times greater, 2 times greater, 3 times greater, etc. According to another example, the first and second leadframes 130, 140 have the same or essentially the same thickness. The thickness t₂ may for example be in the range of about 50 μm to about 2 mm. The lower limit of this range may also be about 100 μm, 150 μm, or 300 μm and the upper limit may also be about 1.5 mm, 1 mm, or 500 μm.

The first and second leadframes 130, 140 may comprise or consist of any suitable metal or metal alloy and may for example comprise or consist of Ag, Al, Au, or Cu. The first and second leadframes 130, 140 may comprise or consist of an identical material or of different materials. The first and/or the second leadframe 130, 140 may comprise suitable plating, e.g. plating comprising or consisting of one or more of Ag, Au, Ni and Pd.

As shown in FIG. 1, the one or more connecting portions 131 extend into the second plane (plane B) at the one or more attachment sites 143. Furthermore, the connecting portions 131 are arranged at a non-zero distance from the second leadframe 140 and the non-zero distance is bridged by the weld seams 150 at the one or more attachment sites 143.

The non-zero distance between the connecting portions 131 and the attachment sites 143 may be the minimum distance between the first leadframe 130 and the second leadframe 140. According to an example, the non-zero distance may be in the range of about 50 μm to about 5 mm. The lower limit of this range may also be about 100 μm, 200 μm, 500 μm, or 550 μm and the upper limit of this range may also be about 3 mm, 2 mm, 1 mm, or 700 μm.

The first and second leadframes 130, 140 being arranged at a non-zero distance from each other may in particular entail that the only physical connection between the first and second leadframes 130, 140 is provided by the weld seams 150.

The weld seams 150 may be made of material of the first leadframe 130 and/or from material of the second leadframe 140 as described in further detail below. The weld seams 150 may in particular be fabricated using a laser welding process, wherein a laser is used to partially melt the connecting portions 131 and/or the attachment sites 143.

The weld seams 150 may comprise burrs arranged on the connecting portions 131 and/or the attachment sites 143. The weld seams 150 may have any suitable shape and any suitable thickness, e.g. a thickness of 50 μm or more, or 100 μm or more, or 200 μm or more, or 500 μm or more, or 1 mm or more, or 3 mm or more.

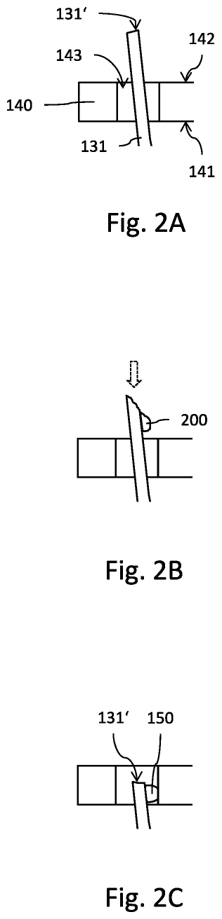

FIGS. 2A to 2C show how the weld seams 150 may be fabricated according to an exemplary method for fabricating the power semiconductor device 100. FIGS. 2A to 2C show a detail view of the section C in FIG. 1 in various stages of fabrication.

FIG. 2A shows a connecting portion 131 and an attachment site 143 of the power semiconductor device 100 prior to the fabrication of the weld seam 150. As shown in FIG. 2A, the connecting portion 131 and the second leadframe 140 do not touch. However, according to another example it is possible that the connecting portion 131 and the second leadframe 140 lightly touch. In this case, “lightly touch” may mean that the connecting portion 131 and the second leadframe 140 touch in such a way that basically no force that could bend or shift the connecting portion 131 and/or the second leadframe 140 is exerted by these parts touching.

As shown in FIG. 2A, the connecting portion 131 may extend to a point above the second side 142 of the second leadframe 140 such that the distal end 131′ of the connecting portion 131 is arranged above the second side 142. According to an example, a distance between the distal end 131′ and the second side 142 of the second substrate 140 is in the range of about 0.2 mm to about 1 mm. The lower limit of this range may also be about 0.3 mm, 0.4 mm, or 0.5 mm and the upper limit may also be about 0.8 mm, 0.7 mm, or 0.6 mm.

As shown in FIG. 2B, the connecting portion 131 is partially molten at the distal end 131′, e.g. using a laser as indicated by the dashed arrow in FIG. 2B. A droplet of molten material 200 may form and flow downwards along the connecting portion 131.

According to the example shown in FIG. 2B, only the connecting portion 131 is molten to form the weld seam 150. However, it is also possible that in a similar manner the connecting portion 131 as well as the second leadframe 140 or only the second leadframe 140 is partially molten to provide the molten material 200. In the latter case, the connecting portion 131 may form the better part of the molten material 200. In order to melt both the connecting portion 131 and the second leadframe 140, the laser beam may be “wobbled” between the connecting portion 131 and the attachment site 143 of the second leadframe 140.

As shown in FIG. 2C, the droplet of molten material 200 flows downwards until it comes into contact with the second leadframe 140 at the attachment site 143 and forms the weld seam 150. The weld seam 150 may bridge the gap between the connecting portion 131 and the second leadframe 140.

In the example shown in FIG. 2C, the distal end 131′ of the connecting portion 131 is arranged below a plane comprising the second side 142 but above a plane comprising the first side 141 of the second leadframe 140. It is however also possible that the distal end 131′ is arranged above the plane comprising the second side 142 at this stage of fabrication of the power semiconductor device 100.

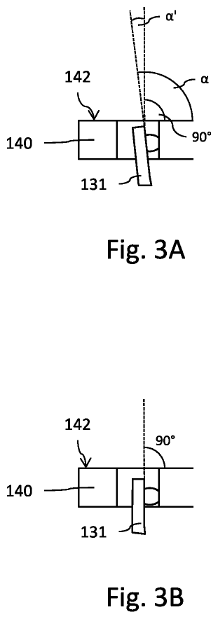

FIGS. 3A and 3B show further detail views of the section C in FIG. 1 according to two different examples of the power semiconductor device 100.

In the example shown in FIG. 3A, the connecting portion 131 (or at least a part of the connecting portion 131) at the attachment site 143 has an angle α of more than 90° (α=α′+90°) relative to the first plane A (compare FIG. 1) and/or to the second plane (plane B) and/or to the second side 142 of the second leadframe 140. According to an example, the angle α is in the range of about 92° to about 125°. The lower limit of this range may also be about 94°, 95°, 96°, or 97° and the upper limit may also be about 120°, 115°, or 110°.

Arranging the connecting portion 131 at an angle in the range described above with respect to the second leadframe 140 may offer one or more of the following advantages: the droplet of molten material 200 may form non-symmetrically on the connecting portion 131 and may more readily flow downwards until contact with the second leadframe 140 is made; this may also make it possible to bridge a larger gap between the connecting portion 131 and the second leadframe 140 with the weld seam 150; the connecting portion 131 may provide a larger target for the laser; it may be easier to insert the second leadframe 140 into the connecting portions 131 (or the other way around).

In the example shown in FIG. 3B, the connecting portion 131 (at least the part of the connecting portion 131 at the attachment site 143) is arranged at an angle of 90° with respect to the second leadframe 140. In this case, the size of the gap between the connecting portion 131 and the second leadframe 140 that can be bridged by the weld seam 150 may be smaller than in the case shown in FIG. 3A. For example, in the case of FIG. 3B, the maximum size of the gap may be about 550 μm or less. The maximum size of the gap in the case of FIG. 3B may for example be equal to about half the thickness t₂ of the second leadframe or about equal to t₂. In the case of FIG. 3A however, the maximum size of the gap may be about three times t₂.

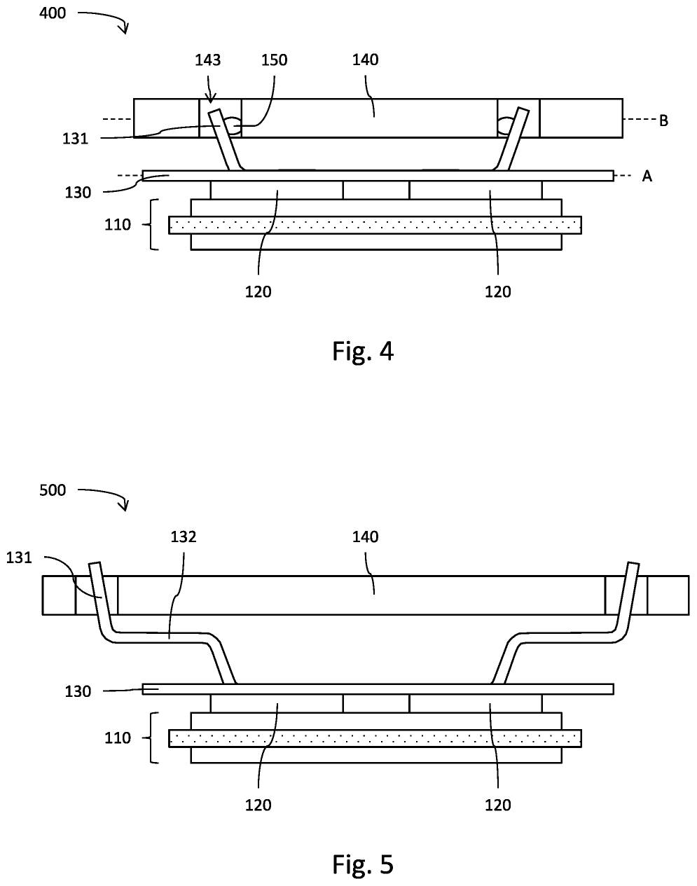

FIG. 4 shows a further power semiconductor device 400 which may be similar or identical to the power semiconductor device 100, except for the differences described in the following.

As shown in FIG. 4, the connecting portions 131 and the weld seams 150 may be arranged vertically above a circumference of the substrate 110 (in FIG. 1, the connecting portions 131 are arranged laterally outside of the circumference of the substrate 110). The first leadframe 130 of the power semiconductor device 400 does not comprise intermediate portions 132 which are at least partially parallel to the first plane and/or the second plane (compare FIGS. 1 and 5).

In the example shown in FIG. 4, parts of the first leadframe 130 which are arranged within the first plane (plane A) extend beyond the circumference of the substrate 110, whereas in the example shown in FIG. 1, only parts of the first leadframe 130 above the first plane extend beyond the circumference of the substrate 110.

FIG. 5 shows a further power semiconductor device 500 which may be similar or identical to the power semiconductor device 400, except for the differences described below.

The power semiconductor device 500 does not comprise the weld seams connecting the connecting portions 131 to the second leadframe 140 because the weld seams are yet to be fabricated. In this stage of fabrication, the second leadframe 140 (and possibly also the first leadframe 130) may be held in place above the substrate by a fixture. The first leadframe 130 may be inserted into the second leadframe 140 in a stress-free manner, in particular in a non-contact manner. This may help in avoiding bending and/or stress in the first and second leadframes 130, 140 after the formation of the weld seams 150. Furthermore, mounting the first and second leadframes 130, 140 in this manner may help in accommodating production tolerances and/or positioning tolerances.

According to the example shown in FIG. 5, the first leadframe 130 comprises one or more intermediate portions 132 connecting the one or more connecting portions 131 to the rest of the first leadframe 130. At least a part of the intermediate portions 132 may have an angle of 20° or less (in particular, an angle of about 0°) relative to the first plane and/or to the second plane.

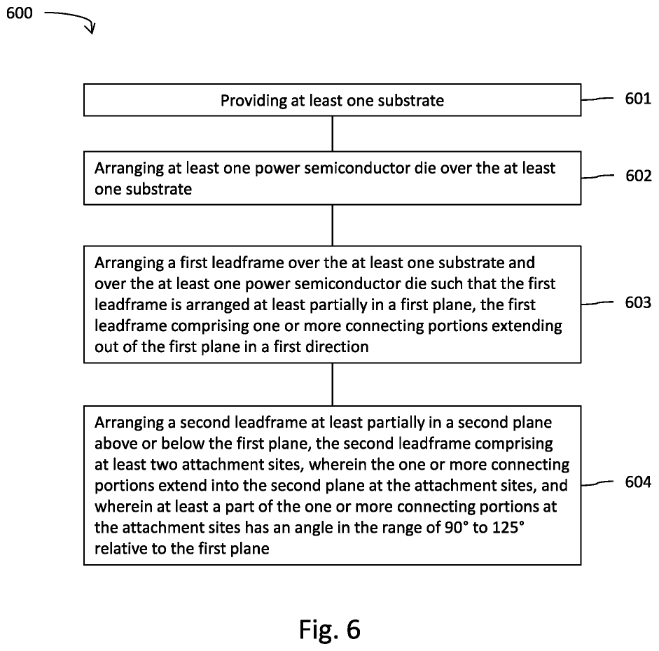

FIG. 6 is a flow chart of a method 600 for fabricating a power semiconductor device. The method 600 may for example be used to fabricate the power semiconductor devices 100, 400 and 500.

The method 600 comprises at 601 a process of providing at least one substrate, at 602 a process of arranging at least one power semiconductor die over the at least one substrate, at 603 a process of arranging a first leadframe over the at least one substrate and over the at least one power semiconductor die such that the first leadframe is arranged at least partially in a first plane, the first leadframe comprising one or more connecting portions extending out of the first plane in a first direction, and at 604 a process of arranging a second leadframe at least partially in a second plane above or below the first plane, the second leadframe comprising at least two attachment sites, wherein the one or more connecting portions extend into the second plane at the attachment sites, and wherein at least a part of the one or more connecting portions at the attachment sites has an angle in the range of 90° to 125° relative to the second plane.

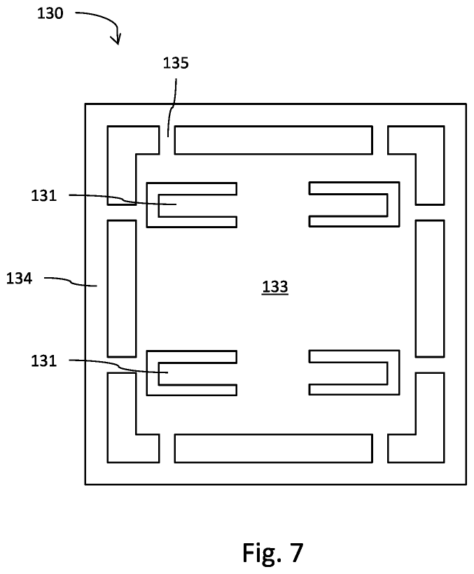

FIG. 7 shows a plan view of the first leadframe 130 according to a specific example. As shown in FIG. 7, the first leadframe 130 may comprise an inner portion 133 and a frame portion 134 at least partially surrounding the inner portion 133. The inner portion 133 and the frame portion 135 may be connected by tie bars 135 which may be cut away in a later stage of fabrication, thereby disengaging the inner portion 133 from the frame portion 134.

As shown in FIG. 7, the one or more connecting portions 131 may be arranged within the inner portion 133 of the first leadframe 130. The inner portion 133 may comprise further structures apart from the connecting portions 131 which however are not shown in FIG. 7 for the sake of clarity.

In the following, the power semiconductor device and the method for fabricating a power semiconductor device are further explained using specific examples.

Example 1 is a power semiconductor device, comprising: at least one substrate, at least one power semiconductor die arranged over the at least one substrate, a first leadframe arranged over the at least one substrate and over the at least one power semiconductor die, the first leadframe being arranged at least partially in a first plane, and the first leadframe comprising one or more connecting portions extending out of the first plane in a first direction, and a second leadframe at least partially arranged in a second plane above or below the first plane, the second leadframe comprising one or more attachment sites, wherein the one or more connecting portions extend into the second plane at the one or more attachment sites, and wherein the connecting portions are arranged at a non-zero distance from the second leadframe, the non-zero distance being bridged by weld seams at the one or more attachment sites.

Example 2 is the power semiconductor device of example 1, wherein the second leadframe has a greater thickness than the first leadframe, the thickness being measured perpendicular to the first plane.

Example 3 is the power semiconductor device of example 1 or 2, wherein at least a part of the one or more connecting portions at the attachment sites is angled 90° relative to the second plane.

Example 4 is the power semiconductor device of one of the preceding examples, wherein a minimum distance between the one or more connecting portions and the second leadframe is in the range of 0.2 mm to 2 mm, in particular 0.4 mm to 0.6 mm.

Example 5 is the power semiconductor device of one of the preceding examples, wherein a minimum distance between the one or more connecting portions and the second leadframe is three times the thickness of the first leadframe or less.

Example 6 is the power semiconductor device of one of the preceding examples, wherein the first and/or the second leadframe has a thickness in the range of 50 μm to 2 mm, in particular 100 μm to 1 mm, more in particular 150 μm to 250 μm.

Example 7 is the power semiconductor device of one of the preceding examples, wherein the first leadframe is attached to an upper side of the at least one power semiconductor die, the upper side facing away from the at least one substrate.

Example 8 is a power semiconductor device, comprising: at least one substrate, at least one power semiconductor die arranged over the at least one substrate, a first leadframe arranged over the at least one substrate and over the at least one power semiconductor die, the first leadframe being arranged at least partially in a first plane, and the first leadframe comprising one or more connecting portions extending out of the first plane in a first direction, and a second leadframe at least partially arranged in a second plane above or below the first plane, the second leadframe comprising one or more attachment sites, wherein the connecting portions extend from the first plane through the attachment sites to a distal end above or below the second plane.

Example 9 is the power semiconductor device of example 8, wherein a distance between the distal end and the second plane is in the range of 0.2 mm to 1 mm, in particular 0.3 mm to 0.8 mm.

Example 10 is the power semiconductor device of example 8 or 9, wherein at least a part of the one or more connecting portions at the attachment sites and above or below the attachment sites is angled 90° relative to the second plane.

Example 11 is the power semiconductor device of example 8 or 9, wherein at least a part of the one or more connecting portions at the attachment sites and above or below the attachment sites has an angle of more than 90° relative to the second plane.

Example 12 is the power semiconductor device of example 11, wherein the angle is in the range of 92° to 125°.

Example 13 is a power semiconductor device, comprising: at least one substrate, at least one power semiconductor die arranged over the at least one substrate, a first leadframe arranged over the at least one substrate and over the at least one power semiconductor die, the first leadframe being arranged at least partially in a first plane, and the first leadframe comprising one or more connecting portions extending out of the first plane in a first direction, and a second leadframe at least partially arranged in a second plane above or below the first plane, the second leadframe comprising one or more attachment sites, wherein the one or more connecting portions extend into the second plane at the one or more attachment sites, and wherein at least a part of the one or more connecting portions at the attachment sites has an angle of more than 90° relative to the second plane.

Example 14 is the power semiconductor device of example 13, wherein the angle is in the range of 92° to 125°.

Example 15 is the power semiconductor device of example 13 or 14, wherein the first leadframe further comprises one or more intermediate portions arranged between the first plane and the second plane, the one or more intermediate portions having an angle of 20° or less relative to the second plane, and the one or more intermediate portions connecting the one or more connecting portions to the rest of the first leadframe.

Example 16 is a method for fabricating a power semiconductor device, the method comprising: providing at least one substrate, arranging at least one power semiconductor die over the at least one substrate, arranging a first leadframe over the at least one substrate and over the at least one power semiconductor die such that the first leadframe is arranged at least partially in a first plane, the first leadframe comprising one or more connecting portions extending out of the first plane in a first direction, and arranging a second leadframe at least partially in a second plane above or below the first plane, the second leadframe comprising at least two attachment sites, wherein the one or more connecting portions extend into the second plane at the attachment sites, and wherein at least a part of the one or more connecting portions at the attachment sites has an angle in the range of 90° to 125° relative to the second plane.

Example 17 is the method of example 16, wherein the connecting portions are arranged at a non-zero distance from the second leadframe, the non-zero distance being bridged by weld seams.

Example 18 is the method of example 16 or 17, further comprising: laser welding the connecting portions to the second leadframe.

Example 19 is an apparatus comprising means for performing the method according to anyone of examples 16 to 18.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A power semiconductor device, comprising:
at least one substrate;
at least one power semiconductor die arranged over the at least one substrate;
a first leadframe arranged over the at least one substrate and over the at least one power semiconductor die, the first leadframe being arranged at least partially in a first plane, and the first leadframe comprising one or more connecting portions extending out of the first plane in a first direction; and
a second leadframe at least partially arranged in a second plane above or below the first plane, the second leadframe comprising one or more attachment sites,
wherein the one or more connecting portions extend into the second plane at the one or more attachment sites,
wherein the one or more connecting portions are arranged at a non-zero distance from the second leadframe, the non-zero distance being bridged by weld seams at the one or more attachment sites.

2. The power semiconductor device of claim 1, wherein the second leadframe has a greater thickness than the first leadframe, the thickness being measured perpendicular to the first plane.

3. The power semiconductor device of claim 1, wherein at least a part of the one or more connecting portions at the one or more attachment sites is angled 90° relative to the second plane.

4. The power semiconductor device of claim 1, wherein a minimum distance between the one or more connecting portions and the second leadframe is in a range of 0.2 mm to 2 mm.

5. The power semiconductor device of claim 1, wherein a minimum distance between the one or more connecting portions and the second leadframe is three times the thickness of the first leadframe or less.

6. The power semiconductor device of claim 1, wherein the first and/or the second leadframe has a thickness in a range of 50 μm to 2 mm.

7. The power semiconductor device of claim 1, wherein the first leadframe is attached to an upper side of the at least one power semiconductor die, the upper side facing away from the at least one substrate.

8. A power semiconductor device, comprising:
at least one substrate;
at least one power semiconductor die arranged over the at least one substrate;
a first leadframe arranged over the at least one substrate and over the at least one power semiconductor die, the first leadframe being arranged at least partially in a first plane, and the first leadframe comprising one or more connecting portions extending out of the first plane in a first direction; and
a second leadframe at least partially arranged in a second plane above or below the first plane, the second leadframe comprising one or more attachment sites,
wherein the one or more connecting portions extend from the first plane through the one or more attachment sites to a distal end above or below the second plane.

9. The power semiconductor device of claim 8, wherein a distance between the distal end and the second plane is in a range of 0.2 mm to 1 mm.

10. The power semiconductor device of claim 8, wherein at least a part of the one or more connecting portions at the one or more attachment sites and above or below the one or more attachment sites is angled 90° relative to the second plane.

11. The power semiconductor device of claim 8, wherein at least a part of the one or more connecting portions at the one or more attachment sites and above or below the one or more attachment sites has an angle of more than 90° relative to the second plane.

12. The power semiconductor device of claim 11, wherein the angle is in a range of 92° to 125°.

13. A power semiconductor device, comprising:
at least one substrate;
at least one power semiconductor die arranged over the at least one substrate;
a first leadframe arranged over the at least one substrate and over the at least one power semiconductor die, the first leadframe being arranged at least partially in a first plane, and the first leadframe comprising one or more connecting portions extending out of the first plane in a first direction; and
a second leadframe at least partially arranged in a second plane above or below the first plane, the second leadframe comprising one or more attachment sites,
wherein the one or more connecting portions extend into the second plane at the one or more attachment sites,
wherein at least a part of the one or more connecting portions at the one or more attachment sites has an angle of more than 90° relative to the second plane.

14. The power semiconductor device of claim 13, wherein the angle is in a range of 92° to 125°.

15. The power semiconductor device of claim 13, wherein the first leadframe further comprises one or more intermediate portions arranged between the first plane and the second plane, the one or more intermediate portions having an angle of 20° or less relative to the second plane, and wherein the one or more intermediate portions connect the one or more connecting portions to the rest of the first leadframe.

16. A method for fabricating a power semiconductor device, the method comprising:
providing at least one substrate;
arranging at least one power semiconductor die over the at least one substrate;
arranging a first leadframe over the at least one substrate and over the at least one power semiconductor die such that the first leadframe is arranged at least partially in a first plane, the first leadframe comprising one or more connecting portions extending out of the first plane in a first direction; and
arranging a second leadframe at least partially in a second plane above or below the first plane, the second leadframe comprising at least two attachment sites,
wherein the one or more connecting portions extend into the second plane at the one or more attachment sites,
wherein at least a part of the one or more connecting portions at the at least two attachment sites has an angle in a range of 90° to 125° relative to the second plane.

17. The method of claim 16, wherein the one or more connecting portions are arranged at a non-zero distance from the second leadframe, the non-zero distance being bridged by weld seams.

18. The method of claim 16, further comprising:
laser welding the one or more connecting portions to the second leadframe.
